(19) United States
(12) Patent Application Publication
(10) Pub. No.: US 2009/0235861 A1
(43) Pub. Date: Sep. 24, 2009

(54) CARBON-DOPED SINGLE CRYSTAL MANUFACTURING METHOD

(75) Inventors: Hideki FUJIWARA, Tokyo (JP); Naoki IKEDA, Tokyo (JP); Kazunari KURITA, Tokyo (JP); Masataka HOURAI, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/406,359

(22) Filed: Mar. 18, 2009

(30) Foreign Application Priority Data
Mar. 18, 2008 (JP) 2008-068872

(51) Int. Cl. C30B 15/14; C30B 15/26

(52) U.S. Cl. 117/21; 117/217; 117/201

(57) ABSTRACT

A method of manufacturing a silicon single crystal with carbon doping in a chamber by using a Czochralski method is provided. In a step of placing a silicon raw material in a crucible, a carbon dopant is disposed at a distance of 5 cm or further away from the inner surface of the crucible, and in this state, a step of melting the silicon raw material is performed after the disposing step.

### BACKGROUND OF THE INVENTION

1. Field of the Invention

The present invention relates to a manufacturing method of a carbon-doped single crystal from which a silicon wafer used as a substrate of a semiconductor device such as a memory or a CPU is cut, and more particularly, to a technique applicable for a carbon-doped single crystal manufacturing method, which controls crystal defects and a BMD density for impurity gettering by using carbon doping that has been used for a high-technology field.

Priority is claimed on Japanese Patent Application No. 2008-068872, filed on Mar. 18, 2008, the content of which is incorporated herein by reference.

2. Description of the Related Art

A silicon single crystal from which a silicon wafer used as a substrate of a semiconductor device such as a memory and a CPU is cut is generally manufactured by a Czochralski Method (hereinafter, referred to as the CZ method).

The silicon single crystal manufactured by the CZ method contains oxygen atoms, and when a device is manufactured by using a silicon wafer cut from the silicon single crystal, oxygen precipitates (bulk micro-defects; hereinafter referred to as BMD) are created by combinations of silicon atoms and oxygen atoms. It is known that the BMD getters contamination atoms such as heavy metal inside the wafer and therefore increase an IG (intrinsic gettering) capability for improving device characteristics, and a higher-performance device can be obtained as the BMD density of the bulk of the wafer increases.

Recently, in order to control crystal defects in a silicon wafer and give a sufficient IG capability, intentionally doping a silicon single crystal that is to be manufactured with carbon or nitrogen has been performed.

As a method of doping a silicon single crystal with carbon, there have been proposed methods using gas doping (JP-A-11-302099), a high-purity carbon powder (JP-A-2002-293691), a carbon mass (JP-A-2003-146796), and the like.

However, there are problems in that with regard to the gas doping, when a dislocation occurs in the crystal, re-melting is impossible, with regard to the high-purity carbon powder, the high-purity carbon powder scatters due to a gas introduced upon raw material melting, and with regard to the carbon mass, it is difficult to melt carbon, and a dislocation in the crystal occurs during growth.

As means for solving the problems, in JP-A-11-312683, a container made of polysilicon which is added with carbon powder, a silicon wafer on which a film is formed from carbon in the vapor phase, a silicon wafer applied with an organic solvent containing carbon particles and baked, and a method of providing polysilicon containing a predetermined amount of carbon in a crucible thereby doping a silicon single crystal with carbon, are disclosed. By using these methods, the above-mentioned problems can be solved. However, these methods require processing of polysilicon and heat treatment of wafers, and preparation of a carbon dopant is not easy. Moreover, contamination may occur from impurities in a process of adjusting the dopant and heat treatment of wafers.

A method of obtaining a silicon single crystal with few grown-in defects and high IG capability by simultaneously adding carbon and nitrogen, is disclosed in JP-A-2001-199794 and International Publication No. 01/79593. As a method of doping a silicon single crystal with nitrogen, a method of mixing a wafer having a silicon nitride film formed on its surface with a polysilicon raw material (for example, see JP-A-5-294780) has been generally used.

Additionally, in order to solve the above-mentioned problems, JP-A-5-294780, JP-A-2006-069852, and JP-A-2005-320203 are proposed.

### SUMMARY OF THE INVENTION

However, in the techniques disclosed in JP-A-5-294780, JP-A-2006-069852, and JP-A-2005-320203, the following problems are not solved:

1. Carbon supplied to a crucible reacts with the inner surface of the crucible after a raw material melts and forms SiC, and the SiC degrades the quality of a pulled single crystal.

2. Although there is a demand for use of carbon powder from the points of raw material purity and costs, bad influences of scattering, adhesion of powder to an unpredictable place caused by low solubility of the powder, SiC formation caused by the aforementioned phenomena, and quality degradation in the pulled single crystal could not be eliminated.

The invention is designed to solve the above-mentioned problems.

According to an aspect of the invention, there is provided a carbon-doped single crystal manufacturing method of manufacturing a silicon single crystal with carbon doping in a chamber by using a Czochralski method, the method including the steps of: in a step of placing a silicon raw material in a crucible, disposing a carbon dopant at a distance of 5 cm or further away from the inner surface of the crucible; and melting the silicon raw material in this state after the disposing step. Accordingly, degradation of single crystal properties caused by a reaction between the added carbon dopant with the inner surface of the crucible to produce SiC, the incorporation of the SiC as impurities during single crystal growth, scattering of the powder-type carbon dopant by the flow of gas thereby resulting in an undesirable carbon concentration in the silicon melt and in the pulled single crystal, low solubility of the powder, a dislocation by the un-melted powder, and the like can be prevented.

In the step of placing the silicon raw material in the crucible, the carbon dopant is disposed at a distance of 5 cm or inwards from the top surface of the placed silicon raw material, and melting of the silicon raw material is performed after the disposing step. Accordingly, since the carbon dopant is safely disposed inside the silicon raw material, the direct flow of gas to the carbon dopant, which flows from a heat cap toward the silicon raw material placed in the crucible before melting, can be reduced. Therefore, although the carbon dopant is powder, the carbon dopant does not scatter, and the position of the carbon dopant is not changed before and during the melting of the silicon raw material, thereby implementing the silicon melt state containing a desired amount of carbon. Consequently, degradation of single crystal properties caused by the reaction between the added carbon dopant with the inner surface of the crucible to produce SiC, the incorporation of the SiC as impurities during single crystal growth, scattering of the powder-type carbon dopant by the gas flow thereby resulting in an undesirable carbon concentration in the silicon melt and in the pulled single crystal, a dislocation, and the like can be prevented.

In the step of placing the silicon raw material in the crucible, the carbon dopant is disposed in the placed silicon raw material, with respect to the height H from the bottom surface of the crucible to the top surface of the silicon raw material, at a position in the range of the center position, that is, H/2, to positions from the center position by H/4 in a vertical direction, and melting of the silicon raw material is performed in this state after the disposing step. Accordingly, since the carbon dopant is safely disposed inside the silicon raw material, the direct flow of gas to the carbon dopant, which flows from the heat cap toward the silicon raw material placed in the crucible before melting, can be reduced. Therefore, although the carbon dopant is powder, the carbon dopant does not scatter, and the position of the carbon dopant is not changed before and during the melting of the silicon raw material. Simultaneously, the carbon dopant does not fall from the position before melting, so that the silicon raw material is not melted while the carbon dopant is close to the bottom surface of the crucible. Therefore, inconveniences such as SiC generation at the bottom surface of the crucible can be reduced, and the silicon melt state containing a desired amount of carbon can be implemented. Consequently, degradation of single crystal properties caused by the reaction between the added carbon dopant with the inner surface of the crucible to produce SiC, the incorporation of the SiC as impurities during single crystal growth, scattering of the powder-type carbon dopant by the gas flow thereby resulting in an undesirable carbon concentration in the silicon melt and in the pulled single crystal, a dislocation, and the like can be prevented.

In the step of placing the silicon raw material in the crucible, the carbon dopant is disposed, with respect to the radius R of the crucible, at a position in the range of the center of the crucible to R/2 in a transverse direction, from a plan view, and in this state, melting of the silicon raw material is performed after the disposing step. Accordingly, since the carbon dopant is safely disposed inside the silicon raw material, contact of the carbon dopant to the inner surface of the crucible during melting of the silicon raw material can be reduced, and inconveniences such as SiC generation at the inner surface of the crucible can be reduced, thereby implementing the silicon melt state containing a desired amount of carbon. Consequently, degradation of single crystal properties caused by the reaction between the added carbon dopant with the inner surface of the crucible to produce SiC, the incorporation of the SiC as impurities during single crystal growth, scattering of the powder-type carbon dopant by the gas flow thereby resulting in an undesirable carbon concentration in the silicon melt and in the pulled single crystal, a dislocation, and the like can be prevented.

The carbon dopant is carbon powder. Accordingly, the dopant with a high level of purity can be used, and the incorporation of undesirable impurities into the single crystal can be prevented, so that degradation of the single crystal properties can be prevented.

The carbon dopant is carbon powder with a purity of 99.999%. Accordingly, the incorporation of undesirable impurities into the single crystal can be prevented, and degradation of the single crystal properties can be prevented.

The placed silicon raw material includes a lumpy raw material of 10 cm² or larger at least from a plan view, the lumpy, silicon raw material has a shape of a plane so as to enable the carbon dopant to be put thereon (the carbon dopant does not fall off), and the carbon dopant is put on the lumpy, silicon raw material. Accordingly, it prevents the carbon dopant from falling from the upper side of the lumpy, silicon raw material where the carbon dopant is disposed before melting, and it prevents the silicon raw material from melting while the carbon dopant is close to or in contact with the bottom surface of the crucible. Therefore, inconveniences such as SiC generation at the bottom surface of the crucible can be reduced, and the silicon melt state containing a desired amount of carbon can be implemented. Consequently, degradation of single crystal properties caused by the reaction between the added carbon dopant with the inner surface of the crucible to produce SiC, the incorporation of the SiC as impurities during single crystal growth, an undesirable carbon concentration in the silicon melt and in the pulled single crystal, a dislocation, and the like can be prevented.

Here, the carbon dopant can be put on the lumpy, silicon raw material. It means that, from a plan view, the silicon raw material has such a size that the carbon dopant put on the silicon raw material does not fall off. In addition, the silicon raw material is flat such that the carbon dopant does not fall off, and when the silicon raw material is placed, the silicon raw material has a concave portion at its surface such that the carbon dopant does not fall off. Specifically, the placed silicon raw material has the concave portion at its top surface, and the vicinity of the concave portion may protrude to have a height of 5 mm from the inner side of the concave portion.

The carbon dopant is in a form of a sheet. Accordingly, a change in position of the carbon dopant due to the flow of gas blown from the heat cap toward the silicon raw material placed in the crucible before melting can be reduced, so that scattering of the carbon dopant and a change in position of the carbon dopant before and during the melting of the silicon raw material can be prevented. Simultaneously, inconveniences such as SiC generation at the bottom surface of the crucible as the carbon dopant falls from the position before melting can be reduced, thereby implementing the silicon melt state containing a desired amount of carbon. Consequently, degradation of single crystal properties caused by the reaction between the added carbon dopant with the inner surface of the crucible to produce SiC, the incorporation of the SiC as impurities during single crystal growth, an undesirable carbon concentration in the silicon melt and in the pulled single crystal according to a change in position of the carbon dopant due to the gas flow, a dislocation, and the like can be prevented.

In addition, the sheet-shaped carbon dopant is formed by weaving carbon fiber into a fabric or a sheet. In addition, as the carbon dopant, strands of carbon fiber or a bundle of several to thousands of carbon fiber strands may be applied. In this case, it is also preferable that carbon with a purity of 99.999% be employed.

The placed silicon raw material includes a lumpy raw material having a slit in which at least the carbon dopant is to be disposed. Accordingly, the slit only needs to be formed at the one or more lumpy silicon raw materials selected in advance. Therefore, it prevents the carbon dopant from falling off, thereby preventing a change in position of the carbon dopant due to the gas flow. In addition, the immersion state of the carbon dopant into the silicon melt can be controlled by the melt state of the silicon raw material, thereby controlling the carbon dopant added to the silicon melt with a high level of precision.

In addition, in the case where a silicon single crystal having a diameter of 300 mm is to be pulled, for an ingot of the silicon single crystal, if the diameter is set to 306 mm, the length of a straight portion is set to 2000 mm, the total weight of the raw material is set to 400 kg, and the carbon concentration of the ingot top portion is set to 1 to 2×10¹⁶ atoms/cc, 470 to 950 mg of carbon is needed Therefore, a sheet-shaped carbon dopant having a thickness of 1 mm requires a size of the carbon dopant of 2.6 to 5.3 cm².

Therefore, when the carbon dopant is in such a form of sheet, it is preferable that the slit have a width of about 1.5 mm, a depth of 10 to 15 mm, a length of 2 cm or longer, and a maximum size equal to or smaller than the maximum size of the silicon raw material mass along the slit. By setting the slit as described above, the sheet-shaped carbon dopant can be easily disposed into the slit.

When the slit having the aforementioned dimensions is formed, a needed amount of carbon can be inserted into the slit with a good precision, the silicon single crystal can be doped with a predetermined amount of high-purity carbon with little variation of the carbon concentration in the growth axis direction without heavy metal contamination and the like, thereby improving the uniformity of the carbon concentration in the growth axis direction.

In addition, when the powder-type carbon dopant is used, it is preferable that the slit have a width of about 3 mm, a depth of 10 to 15 mm, a length of 2 cm or longer, and a maximum size equal to or smaller than the maximum size of the silicon raw material mass along the slit. By setting the slit as described above, the powder-type carbon dopant can be easily inserted into the slit.

The slit of the silicon raw material has such a size that at least half the area of the sheet-shaped carbon dopant is inserted into the slit. Accordingly, a change in position of the carbon dopant can be prevented.

Specifically, when the carbon dopant is in a form of a sheet, it is preferable that the slit have a width of about 1 mm, a depth of 5 to 7 mm, a length of 1.5 cm or longer, and a maximum size equal to or smaller than the maximum size of silicon raw material mass along the slit. By setting the slit as described above, the carbon dopant can be easily inserted into the slit.

In a step of controlling a melting state after the disposing step, the lower end of a heat cap which is disposed concentrically above the crucible and substantially cylindrical is at a height of 20 to 50 cm from the top surface of the placed silicon raw material, and in this state, melting of the silicon raw material is started. Accordingly, a change in position of the carbon dopant due to the flow of gas blown from the heat cap toward the silicon raw material placed in the crucible before melting can be prevented, and the influence of the gas flow toward the carbon dopant can be reduced. Consequently, although the carbon dopant is powder, the position of the carbon dopant is not changed before and during the melting of the silicon raw material.

Simultaneously, the influence of the gas flow on the carbon dopant between the placement of the silicon raw material before melting and the melting can be reduced. Accordingly, without the movement of the carbon dopant from the position and melting of the silicon raw material while the carbon dopant is close to the inner surface of the crucible, inconveniences such as SiC generation at the inner surface of the crucible can be reduced, thereby implementing the silicon melt state containing a desired amount of carbon. Consequently, degradation of single crystal properties caused by the incorporation of the SiC generated by the reaction between the carbon dopant and the inner surface of the crucible during single crystal growth as impurities, scattering of the powder-type carbon dopant during the single crystal growth thereby resulting in an undesirable carbon concentration in the silicon melt and in the pulled single crystal, a dislocation, and the like can be prevented.

In the step of controlling the melting state, the internal pressure of a furnace in the chamber is set to be in the range of 2 to 13.3 kPa, the gas flow rate of a gas flowing from the upper side of the heat cap toward the crucible is set to be in the range of 3 to 150 L/min, and in this state, melting of the silicon raw material is started. More preferably, the internal pressure of the furnace in the chamber may be set to 6.667 kPa (50 torr), and the gas flow rate of the gas flowing from the upper side of the heat cap toward the crucible may be set to 50 L/min. When the gas flow rate is greater than the above-mentioned range and/or the internal pressure of the furnace is smaller than the level, the flow of gas flowing from the upper side of the heat cap toward the crucible becomes stronger. In this case, there are possibilities that the position of the carbon dopant may be changed by the gas flow and the powder-type carbon dopant may scatter when disposed, which is not preferable. In addition, when the gas flow rate is smaller than the above-mentioned range and/or the internal pressure of the furnace is greater than the range, SiO particles that evaporate from the melt surface and coagulate cannot be effectively exhausted, and desirable characteristics of the single crystal under pulling cannot be obtained, which is not preferable.

In the melting step, a heater is controlled so that the upper side of the silicon raw material melts before the lower side thereof melts. Accordingly, undesirable properties of the pulled single crystal caused by: a phenomenon in which when the silicon raw material melts, a silicon melt is formed as the silicon raw material melts at the lower portion of the crucible, but the raw material does not melt and remains as a solid at the inner wall of the crucible at the upper portion of the crucible, called a bridge; a phenomenon in which a portion of the silicon raw material sticks to the side wall of the upper portion of the crucible and remains as a solid to cause the bridge; a phenomenon in which when the crucible is continuously heated to melt the raw material while the silicon raw material sticks to the inner wall of the crucible as a solid, the carbon dopant cannot be immersed into the melt and this causes an undesirable value of the carbon concentration in the silicon melt, can be prevented.

Additionally, degradation of the properties of the pulled single crystal caused by a deformation of the crucible which is softened by heating due to the bridge and the weight of the sticking raw material, a state in which the deformation is too significant to perform pulling, a problem in which the raw material remaining as the solid and the bridge fall into the silicon melt in the crucible to damage the inner wall of the crucible, and the damage of the inner wall of the crucible, can be prevented.

Here, in order to control the heater so as to melt the upper side of the silicon raw material before the lower side thereof, in the case of a constitution including upper side and lower side heaters provided around the crucible, specifically, the output of the upper side heater is controlled to be 1.05 to 2.3 times the output of the lower side heater at the time the melting is started, and the output of the upper side heater is controlled to be 1.05 to 0.95 times the output of the lower side heater when the fluid level of the silicon melt is reduced to a fluid level that is about half the fluid level at the time the pulling is started.

In addition, specifically, in the case of a constitution including side heaters provided around the crucible and a bottom heater provided below the bottom portion of the crucible, at the time the melting is started, power is not supplied to the bottom heater, and when the fluid level of the silicon melt is reduced to a fluid level that is about half the fluid level at the time the pulling is started, the output of the bottom heater is controlled to be 0.5 to 1.05 times the output of the side heaters.

In the melting step, a magnetic field is applied to the crucible to generate such a temperature gradient that the temperature of the peripheral portion of the crucible is higher than that of the center portion of the crucible. During the melting of the silicon raw material, at the silicon melt surface, a convection current of the melt flowing toward the center of the crucible occurs and the carbon dopant flows toward the center of the crucible, thereby preventing the carbon dopant from sticking to the inner wall of the crucible to generate SiC. In addition, the generation of the aforementioned bridge and adhesion of the silicon raw material in the solid state to the inner wall of the crucible can be prevented.

When melting is started, with regard to the magnetic field strength, the strength of the horizontal magnetic field is set to 1000 G or greater, the strength of the cusp magnetic field is set to 300 G or greater, and the center height of the magnetic field is set to be within the range from the bottom to the upper end of the crucible. In addition, in the melting step, with regard to a time T from the start of melting to the end of melting, the center height of the magnetic field from the start of melting to T/3, is set to be in the range of ⅛ to ⅓ of the height of the crucible from the bottom of the crucible, the center height of the magnetic field from the 2T/3 to the pulling end, is set to be in the range of the silicon melt surface at the time of end of melting to 10 cm from the silicon melt surface in a vertical direction, and the height of the applied magnetic field from T/3 to 2T/3, is controlled to correspond to the height of the crucible which is changed as the raw material melts, so as to be moved slowly from the height at the start to the height at the end. In addition, in the melting step, with regard to a time T from the start of melting to the end of melting, the magnetic field strength from 2T/3 to the end, is set to be constant at the highest strength, the magnetic field strength from the start to T/3, is set to be in the range of ⅛ to ⅓ of the highest strength, and the strength of the applied magnetic field from T/3 to 2T/3, is controlled to gradually change from the level at the start to the level at the end. Accordingly, when the silicon raw material melts, undesirable flow of the melt toward the carbon dopant can be prevented. In addition, after most of the solid silicon raw material melts, undesirable convention current toward the carbon dopant is prevented, thereby controlling the behavior of carbon in the silicon melt. Therefore, bad influences on the crystal under pulling can be prevented.

Specifically, when 400 kg of a melt is prepared to pull a crystal having a diameter of 300 mm, for 6 hours after the start of melting, the magnetic field center is at a height of 70 mm from the bottom surface of the crucible, for 12 hours thereafter, the magnetic field center is moved to a position below the liquid surface by 80 mm, and until the raw material melting ends, the magnetic field center is fixed at the position. Here, a time needed for the raw material melting was about 18 hours.

The RMS roughness of the inner surface of the crucible is set to be in the range of 3 to 50 nm. Accordingly, it prevents the carbon dopant from sticking to the inner surface of the crucible to form SiC.

A devitrification layer of 10 to 1000 μm is formed at the inner surface of the crucible. Accordingly, it prevents the carbon dopant from sticking to the inner surface of the crucible to form SiC.

In the melting step, the crucible is rotated at 1 to 5 rpm and reversed at a period of 15 to 300 sec intervals. Accordingly, it prevents the carbon dopant from sticking to the inner surface of the crucible to form SiC. In addition, degradation of the crystal properties caused by the generation of the aforementioned bridge and adhesion of the solid silicon raw material to the inner surface of the crucible can be prevented.

In addition, the rotation speed of the crucible can be changed periodically in the range of 0 to 5 rpm, and the rotation of the crucible may include a pause. Accordingly, by an increase in centrifugal force with an increase in angular velocity, the carbon dopant that does not melt and remains or the SiC as small impurities mixed with the melt is moved outwards to the wall of the crucible against the flow toward the center. Thereafter, when the angular velocity is reduced to reduce the centrifugal force, the small impurities may tend to move inwards by the flow toward the center of the crucible from the wall of the crucible. However, by an increase in centrifugal force with another increase in angular velocity, it is moved toward the wall of the crucible. By repeating this, the small impurities maintain the state of being accumulated in the vicinity of the wall of the crucible.

In addition, by reversing the crucible, the flow of the melt in the crucible can be changed, and while the impurities are not in contact with the inner wall of the crucible, the carbon dopant which does not melt and remains can be melted sufficiently.

In addition, 1×10⁻⁶ to 10 g of the carbon dopant is disposed in the crucible. Accordingly, a single crystal having the carbon concentration in a desired range can be pulled. In addition, the manufacturing method prevents inconveniences such as scattering, so that degradation of the crystal properties caused by the SiC generated as the carbon dopant sticks to the inner surface of the crucible can be prevented.

Here, the single crystal under pulling may have a diameter of 300 mm, a length of about 1500 to 3000 mm, and a mass of 300 to 550 kg.

An oxygen concentration and a carbon concentration are controlled to be 0.1 to 18×10¹⁷ atoms/cm³ (OLDASTM method) and 20×10¹⁶ atoms/cm³ (NEW ASTM method), respectively, in the pulled silicon single crystal. Accordingly, a silicon single crystal for manufacturing a wafer in which BMDs functioning as gettering sites for enough IG effects are generated in a desirable state can be pulled.

Control is made to allow the specific resistance of a wafer sliced from the pulled silicon single crystal to be in the range of 0.1 to 99 Ω·cm. Accordingly, when a low-resistant wafer having a small amount of added impurities such as boron (B) and arsenic (As) is to be manufactured, a silicon single crystal for a wafer in which BMDs functioning as gettering sites for enough IG effects are generated in a desirable state can be pulled.

In a step of pulling a single crystal after the melting step, the lower end of a heat cap which is disposed concentrically above the crucible and substantially cylindrical is at a height of 1 to 20 cm from the silicon melt surface in order to reduce the flow of the melt flowing from the inner surface toward the center portion of the crucible at the silicon melt surface. Accordingly, the generation of DF fragments and the like caused by the incorporation of SiC and the like at the melt surface flowing toward a solid-liquid interface into the crystal by the flow of the melt flowing from the inner wall of the crucible toward the single crystal under pulling in the melt during the pulling due to the flow of gas blown from the inner side of the heat cap toward the silicon melt surface to flow from the center portion of the crucible outwards in the vicinity of the melt surface, can be prevented.

In a pulling state controlling step performed until the pulling step is started after the melting step, the lower end of a heat cap which is disposed concentrically above the crucible and substantially cylindrical is at a height of 10 to 50 cm from the silicon melt surface. Accordingly, with regard to the lower end of the heat cap which is spaced apart from the heater such that the temperature of the lower end of the heat cap does not increase in the melting step performed at a high temperature, between the melting step and the time of pulling start, the flow of the melt from the center portion of the crucible toward the inner wall of the crucible is formed, and the generation of SiC caused by the carbon dopant which flows toward and contacts to the inner wall of the crucible when the carbon dopant exists at the melt surface can be prevented.

In addition, in the pulling state controlling step, that is, after forming the melt by melting the silicon raw material and the carbon dopant in the crucible, the surface temperature of the melt can be maintained to be higher than the melting point of the crystal raw material by 15° C. or higher for 2 or more hours. Specifically, it is preferable that the surface temperature of the melt be higher than the melting point of the silicon raw material by 20° C. or higher, and a time to leave the melt be equal to or less than 10 hours. Accordingly, the carbon dopant and the like which usually dissolved and remained in the melt in the conventional art are thoroughly dissolved in the silicon melt. Consequently, one of the causes of generation of a dislocation during the subsequent pulling step, that is, a problem in which the carbon dopant melts and remains in the melt can be solved, thereby reducing the number of dislocations of the single crystal that may occur during crystal growth. Consequently, productivity and a yield during the manufacturing of the single crystal can be enhanced.

In a step of pulling a single crystal after the melting step, from a plan view at the lower end of a heat cap which is disposed concentrically above the crucible and substantially cylindrical to reduce the flow of the melt flowing from the inner surface toward the center portion of the crucible at the silicon melt surface, the internal pressure of a furnace in the chamber is set to be in the range of 1.3 to 6.6 kPa, and the gas flow rate of a gas flowing from the upper side of the heat cap toward the crucible is set to be in the range of 3 to 150 L/min, in order to prevent the incorporation of factors such as SiC and impurities which cause dislocations. Accordingly, the generation of DF fragments and the like caused by the incorporation of SiC and the like at the melt surface flowing toward a solid-liquid interface into the crystal by the flow of the melt flowing from the inner wall of the crucible toward the single crystal under pulling in the melt during the pulling due to the flow of gas blown from the inner side of the heat cap toward the silicon melt surface to flow from the center portion of the crucible outwards in the vicinity of the melt surface, can be prevented.

In a step of pulling a single crystal after the melting step, from a plan view at the lower end of a heat cap which is disposed concentrically above the crucible and substantially cylindrical to reduce the flow of the melt flowing from the inner surface toward the center portion of the crucible at the silicon melt surface, the heater output is controlled so that the solid-liquid interface between the silicon melt and the single crystal is convex, in order to prevent the incorporation of SiC. Accordingly, the generation of DF fragments and the like caused by the incorporation of SiC and the like at the melt surface flowing toward a solid-liquid interface into the crystal by the convention current of the melt flowing from the inner wall of the crucible toward the single crystal in the melt during the pulling, can be prevented.

In a step of pulling a single crystal after the melting step, the pulling rate of a straight portion of a single crystal is in the range of 0.1 to 1.5 mm/min. Accordingly, crystal properties of the carbon-doped crystal can be improved.

According to another aspect of the invention, there is provided a carbon-doped single crystal manufacturing apparatus for pulling a single crystal by the method, including: a chamber; a crucible in the chamber; a side heater provided in the vicinity of the crucible; and dopant position setting means for setting the position of a carbon dopant to be disposed at a distance of 5 cm or further away from the inner surface of the crucible when a silicon raw material is placed in the crucible. Accordingly, degradation of single crystal properties caused by a reaction between the added carbon dopant with the inner surface of the crucible to produce SiC, the incorporation of the SiC as impurities during single crystal growth, scattering of the powder-type carbon dopant by the flow of gas thereby resulting in an undesirable carbon concentration in the silicon melt and in the pulled single crystal, low solubility of the powder, a dislocation by the un-melted powder, and the like can be prevented.

The dopant position setting means may include: detection means for detecting the upper end position of the crucible, and the height and horizontal position of the carbon dopant as the relative positions to the crucible; and display means for displaying the output from the detection means. In addition, the dopant position setting means may include: memory means for registering position data on the carbon dopant in advance; computing means for comparing the output of the detection means to the data of the memory means; and the display means for displaying the computational result. In addition, the dopant position setting means may include: a crucible upper end position detection bar member hung at the side wall of the crucible to pass through the center position of the crucible; and a height setting bar member (and a horizontal range/position setting member which is provided at the lower end of the height setting bar member to set a horizontal range) provided vertically downward from the center position of the crucible upper end position detection bar member. Accordingly, the position of the carbon dopant can be efficiently checked and set.

According to the invention, degradation of single crystal properties caused by a reaction between the added carbon dopant with the inner surface of the crucible to produce SiC, the incorporation of the SiC as impurities during single crystal growth, scattering of the powder-type carbon dopant by the flow of gas thereby resulting in an undesirable carbon concentration in the silicon melt and in the pulled single crystal, a dislocation by the un-melted powder, and the like can be prevented.

### BRIEF DESCRIPTION OF THE DRAWINGS

FIG. 1 is a front view illustrating a part of a carbon-doped single crystal manufacturing apparatus according to an embodiment.

FIG. 2 is a flowchart of a carbon-doped single crystal manufacturing method according to the embodiment.

FIG. 3 is a front sectional view illustrating a disposing method in the carbon-doped single crystal manufacturing method according to the embodiment.

FIG. 4 is a front sectional view for illustrating another disposing method in the carbon-doped single crystal manufacturing method according to the embodiment.

FIG. 5 is a front sectional view illustrating a disposing method in the carbon-doped single crystal manufacturing method according to the embodiment.

FIG. 6A is a perspective view illustrating a silicon raw material used in the carbon-doped single crystal manufacturing method according to the embodiment.

FIG. 6B is a plan view illustrating the silicon raw material used in the carbon-doped single crystal manufacturing method according to the embodiment.

FIG. 7A is a plan view illustrating a disposing method in the carbon-doped single crystal manufacturing method according to the embodiment.

FIG. 7B is a front sectional view illustrating the disposing method in the carbon-doped single crystal manufacturing method according to the embodiment.

FIG. 8 is a front view illustrating the height of a heat cap used in the carbon-doped single crystal manufacturing method according to the embodiment.

FIG. 9 is front view illustrating a pulling step in the carbon-doped single crystal manufacturing method according to the embodiment.

FIG. 10 is an example of a time chart of heat powers in the carbon-doped single crystal manufacturing method according to the embodiment.

FIG. 11 is an example of a time chart of a distance between the heat cap and the raw material surface in the carbon-doped single crystal manufacturing method according to the embodiment.

FIG. 12 is an example of a time chart of a gas flow rate in the carbon-doped single crystal manufacturing method according to the embodiment.

FIG. 13 is an example of a time chart of a furnace internal pressure in the carbon-doped single crystal manufacturing method according to the embodiment.

FIG. 14 is an example of a time chart of a magnetic field strength in the carbon-doped single crystal manufacturing method according to the embodiment.

FIG. 15 is an example of a time chart of a distance between a magnetic field center and a crucible used in the carbon-doped single crystal manufacturing method according to the embodiment.

FIG. 16 is an example of a time chart of crucible rotations in the carbon-doped single crystal manufacturing method according to the embodiment.

FIG. 17 is an example of a time chart of a crucible rotation change pattern in the carbon-doped single crystal manufacturing method according to the embodiment.

FIG. 18 illustrate evaluation results of the oxygen concentration, the specific resistance, and the carbon concentration of a crystal pulled in the carbon-doped single crystal manufacturing method according to the embodiment.

### DETAILED DESCRIPTION OF THE INVENTION

Hereinafter, a carbon-doped single crystal manufacturing method according to an embodiment of the invention will be described with reference to the accompanying drawings.

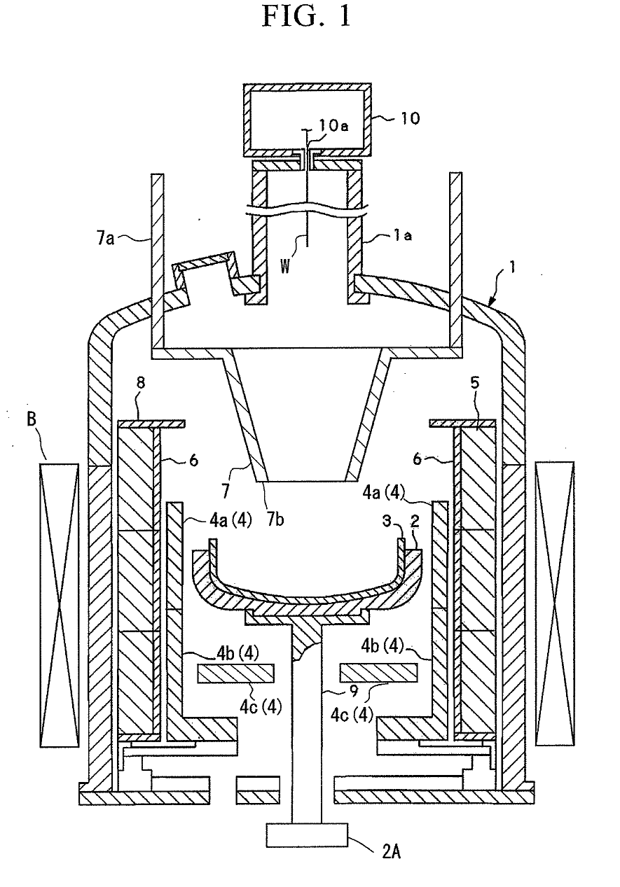

FIG. 1 is a front view illustrating a portion of a carbon-doped single crystal manufacturing apparatus according to the embodiment. In FIG. 1, a reference numeral 1 denotes a chamber of the carbon-doped single crystal manufacturing apparatus (single-crystal pulling apparatus) using a CZ method.

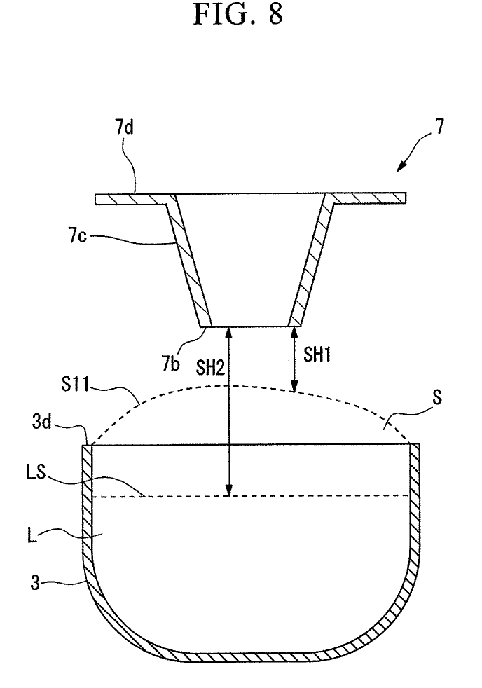

The carbon-doped single crystal manufacturing apparatus includes, as illustrated in FIG. 1, the chamber 1 which is a sealed container, a susceptor 2 made of carbon which is provided inside the chamber 1, a quartz crucible 3 disposed on the susceptor 2, a shaft 9 supporting the susceptor 2 on which the crucible 3 is disposed to move vertically, rotation control means 2A for controlling the upward and downward movements and the rotation of the shaft 9, a heater 4 (including upper and lower side heaters 4a and 4b which are cylindrical and a substantially disk-shaped bottom heater 4c) which is made of carbon and disposed around the crucible 3, a thermal insulation pipe 5 disposed on the outer side, a carbon plate 6 provided as a supporting plate at the inner surface of the thermal insulation pipe 5, a heat cap (flow tube) 7 having a cylindrical flow tube 7c which is provided above the crucible 3 with a diameter decreasing in a downward direction and a flange portion 7d provided at the top of the tube 7c, supporting means 7a (see FIG. 8) which is provided to be perpendicular to the flange portion 7d to support the heat cap 7 to move vertically, height control means not shown for controlling the height of the supporting means 7a, a wire W for pulling a single crystal, a head portion 10 including an apparatus for winding the wire W up, and magnetic field applying means B.

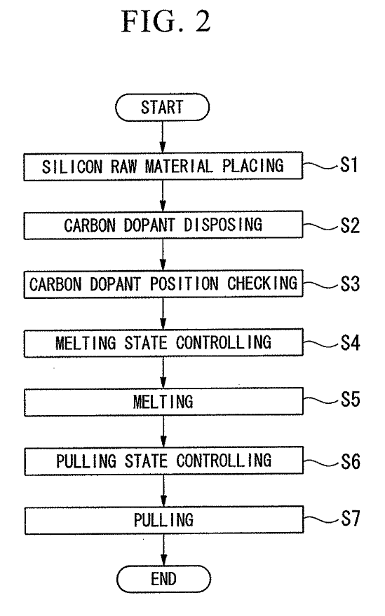

FIG. 2 is a flowchart of a carbon-doped single crystal manufacturing method according to the embodiment.

In this embodiment, the carbon-doped single crystal manufacturing method includes, as illustrated in FIG. 2, a silicon raw material placing step S1, a carbon dopant disposing step S2, a carbon dopant position checking step S3, a melting state controlling step S4, a melting step S5, a pulling state controlling step S6, and a pulling step S7.

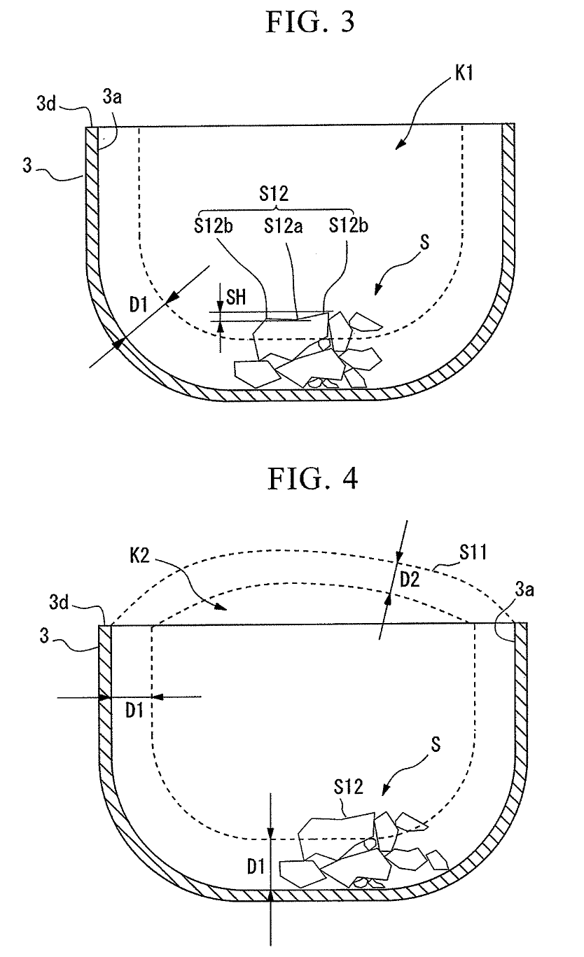

FIGS. 3 and 4 are front sectional views for illustrating disposing methods in the carbon-doped single crystal manufacturing method according to the embodiment.

In the silicon raw material placing step S1, when a silicon raw material S is placed in the crucible 3, it is preferable that a carbon dopant be disposed at a distance of D1, that is, 5 cm or further away from the inner surface 3a of the crucible 3 to be disposed inside a region K1 illustrated in FIG. 3. Additionally, in the silicon raw material placing step S1, it is preferable that the carbon dopant be disposed at a distance of D2, that is, 5 cm or further away from the top surface S11 of the silicon raw material S to be disposed inside a region K2 illustrated in FIG. 4.

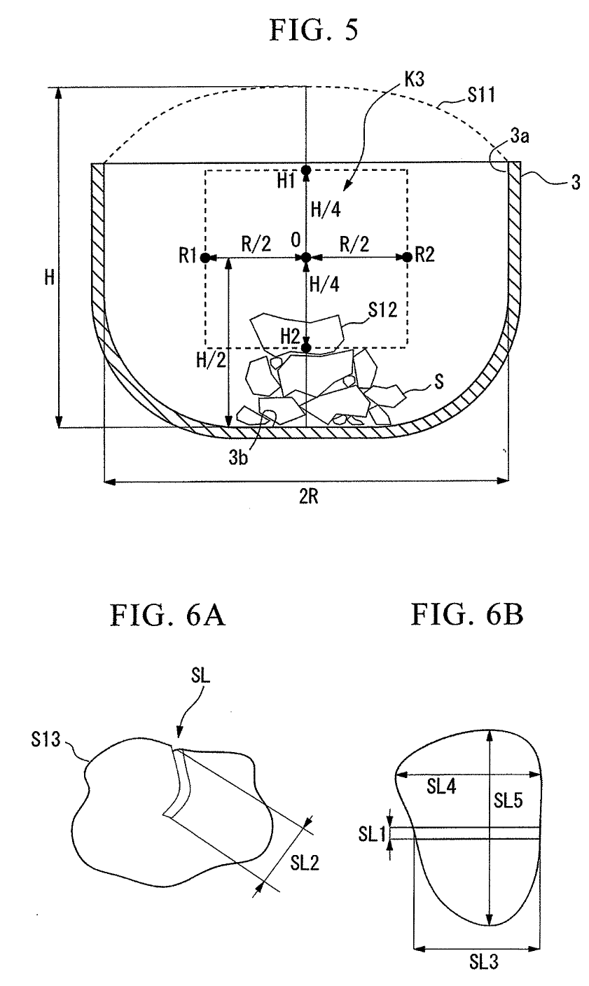

FIG. 5 is a front sectional view illustrating a disposing method in the carbon-doped single crystal manufacturing method according to the embodiment.

Additionally, in the silicon raw material placing step S1, it is preferable that with respect to the height H from the crucible bottom surface 3b of the crucible 3 to the silicon raw material top surface S11 in the placed silicon raw material S, the carbon dopant be disposed (provided) at a position between the height H1 above the height H/2 that is the center position O by H/4 and the height H2 below the height H/2 by H/4, that is, disposed in a region K3 illustrated in FIG. 5. In addition, it is preferable that the carbon dopant be disposed in the range between R1 and R2 both of which are positions at a distance of R/2 from the center O of the crucible 3 from a plan view, that is, in a region K3 illustrated in FIG. 5.

In the carbon dopant disposing step S2, the disposed carbon dopant may be carbon powder, and the carbon powder in this case may have a purity of 99.999%.

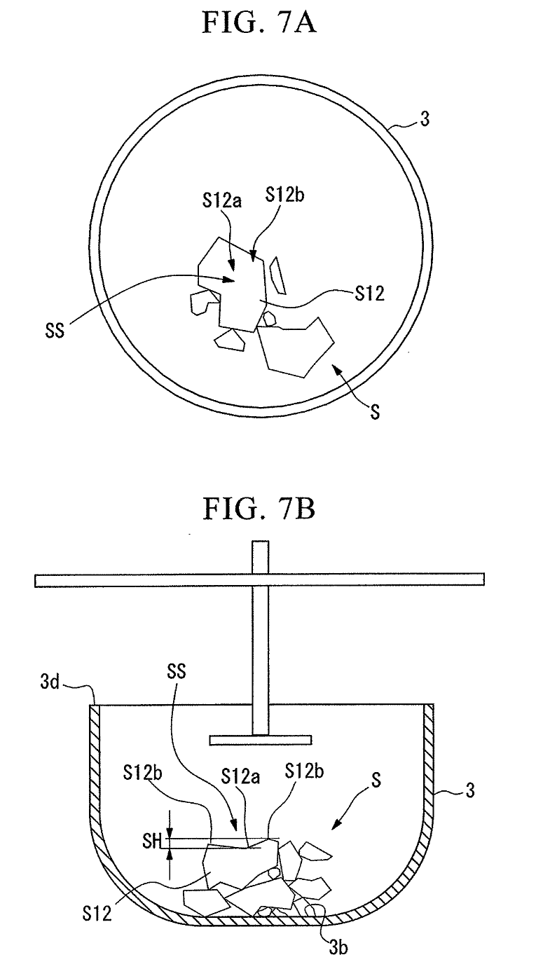

FIG. 7A is a plan view and FIG. 7B is a front sectional view, illustrating the disposing method in the carbon-doped single crystal manufacturing method according to the embodiment.

In the carbon dopant disposing step S2, the placed silicon raw material S is, as illustrated in FIGS. 3 to 5 and 7, a lumpy raw material S12 of 10 cm² or larger at least from a plan view, and the lumpy silicon raw material S 12 has a shape of a plane so as to enable the carbon dopant to be put thereon. In addition, as shown by an arrow SS in FIG. 7, since the carbon dopant is put on the lumpy, silicon raw material S12, it prevents the carbon dopant from falling from the top portion of the lumpy, silicon raw material S12 where the carbon dopant is disposed before melting, and it prevents the silicon raw material S from melting while the carbon dopant is close to or in contact with the crucible bottom surface 3b.

Here, the lumpy silicon raw material S12 has a shape of a plane so as to enable the carbon dopant to be put thereon. Specifically, from a plan view, the silicon raw material S12 has such a size that the carbon dopant put on the silicon raw material S12 does not fall off. In addition, it is satisfactory if the silicon raw material S12 is flat in a degree of preventing the carbon dopant from falling off and the silicon raw material S12 has a concave portion S12a at its top surface in a degree of preventing the carbon dopant from falling off when the silicon raw material is placed while a peripheral portion S12b of the convex portion S12a is protruded to have a height of about 5 mm as a height dimension SH from the inner side of the concave portion S12a.

In the carbon dopant disposing step S2, the carbon dopant is in a form of a sheet, and the sheet-shaped carbon dopant is formed by weaving carbon fiber into a fabric or a sheet. In addition, as the carbon dopant, strands of carbon fiber or a bundle of several to thousands of carbon fiber strands may be applied. In this case, carbon with a purity of 99.999% is employed. The sheet-shaped carbon dopant has a size of about 1 cm².

FIG. 6A is a perspective view and FIG. 6B is a plan view, illustrating the silicon raw material used in the carbon-doped single crystal manufacturing method according to the embodiment.

Here, as illustrated in FIG. 6, the silicon raw material S1 3 is a lumpy raw material with a slit SL into which the carbon dopant is to be inserted. When the carbon dopant is formed as a sheet having a size of about 1 cm², the slit SL is set to have such dimensions that at least half the area of the sheet-shaped carbon dopant is inserted into the slit. Specifically, it is preferable that the slit have a width SL1 of about 3 mm, a depth SL2 of 10 to 15 mm, a length SL3 of 2 cm or longer, and a maximum size equal to or smaller than the maximum size SL4 of silicon raw material mass along the slit, and the slit is set to have the aforementioned dimensions. Here, the slit SL does not have to be formed in the direction along the maximum length SL5 of the silicon raw material S13 and may be in any direction as long as the slit SL is set to have a length SL of 1.5 cm or longer to enable the carbon dopant to be inserted into the slit.

In addition, when the powder-type carbon dopant is used, it is preferable that the slit SL have a width SL1 of about 2 mm, a depth SL2 of 5 to 10 mm, a length SL3 of 1.5 cm or longer, and a maximum size equal to or smaller than the maximum size SL4 of the silicon raw material mass along the slit. By setting the dimensions of the slit as described above, the powder-type carbon dopant can be easily inserted into the slit.

In the carbon dopant position checking step S3, by using dopant position setting means 20 illustrated in FIG. 7, the position of the carbon dopant disposed in the carbon dopant disposing step S2 is checked.

The dopant position setting means 20 according to the embodiment includes detection means 20a for detecting the position of the upper end 3d of the crucible 3, and the height and horizontal position of the carbon dopant as the relative positions to the crucible 3, and display means 20b for displaying the output from the detection means 20a. In addition, as illustrated in FIG. 7, the dopant position setting means 20 further includes a crucible upper end position detection bar member 21 hung at the inner side wall 3a of the crucible 3 to pass through the center position of the crucible 3, a height setting bar member 22 provided vertically downward from the center position of the crucible upper end position detection bar member 21 to move in a vertical direction, and a horizontal range/position setting member 23 which has a shape of a disk and is provided at the lower end of the height setting bar member 22 to set a horizontal range.

Here, the height setting bar member 22 is provided with a scale to indicate the height of the horizontal range/position setting member 23 with respect to the position of the upper end 3d of the crucible 3, and the scale constitutes the display means 20b. In addition, the crucible upper end position defection bar member 21, the height setting bar member 22, and the horizontal range/position setting member 23 constitute the detection means 20a.

In the carbon dopant position checking step S3, the crucible upper end position detection bar member 21 is put on the upper end 3d of the crucible 3 to allow the height setting bar member 22 to be aligned with the center position of the crucible 3, and the horizontal range/position setting member 23 is moved down so as not to contact to the silicon raw material, and the scale of the detection means 20b is then read. Accordingly, whether or not the carbon dopant is in the ranges of K1 to K3 set in advance is checked, thereby setting a height to the range. In addition, from a plan view, depending on whether or not the position of the carbon dopant is covered by the horizontal range/position setting member 23, whether or not the horizontal position of the carbon dopant is in the range of K1 to K3 set in advance can be checked, thereby setting a horizontal position to the range.

In addition, the dopant position setting means includes memory means for registering position data on the carbon dopant in advance, computing means for comparing the output of the detection means to the data of the memory means, and the display means for displaying the computational result.

FIG. 8 is a front view illustrating the height of the heat cap used in the carbon-doped single crystal manufacturing method according to the embodiment.

In the melting state controlling step S4, as illustrated in FIG. 8, the lower end 7b of the flow tube 7c of the heat cap 7 disposed concentrically above the crucible 3 is at a height SH1 of 20 to 50 cm from the top surface S11 of the placed silicon raw material S, and at this state the melting step S5 of melting the silicon raw material is started.

In the melting state controlling step S4, the internal pressure of a furnace in the chamber 1 is set to be in the range of 2 to 13.3 kPa, the gas flow rate of a gas flowing from the upper side of the heat cap 7 toward the crucible 3 is set to be in the range of 3 to 150 L/min, and at this state the following melting step S5 is started. More preferably, the internal pressure of the furnace in the chamber 1 is set to 6.667 kPa (50 torr), and the gas flow rate of the gas flowing from the upper side of the heat cap 7 toward the crucible 3 is set to 50 L/min. When the gas flow rate is greater than the range and/or the internal pressure of the furnace is smaller than the range, the flow of gas flowing from the upper side of the heat cap 7 toward the crucible 3 becomes stronger. In this case, there are possibilities that the position of the carbon dopant may be changed by the gas flow and the powder-type carbon dopant may scatter when disposed, which is not preferable. In addition, when the gas flow rate is smaller than the range and/or the internal pressure of the furnace is greater than the range, SiO particles that evaporate from the melt surface and coagulate cannot be effectively exhausted, and desirable characteristics of the single crystal under pulling cannot be obtained, which is not preferable.

In the melting step S5, the heater 4 is controlled so that the upper side of the silicon raw material S melts before the lower side thereof melts.

Specifically, at the time the melting is started, of the heaters around the crucible 3 illustrated in FIG. 1, the output of the upper side heater 4a is controlled to be 1.05 to 2.3 times the output of the lower side heater 4b. In addition, when the fluid level of the silicon melt L is reduced to a fluid level that is about half the fluid level LS at the time pulling is started, the output of the upper side heater 4a is controlled to be 1.05 to 0.95 times the output of the lower side heater 4b.

In addition, at the time the melting is started, power is not supplied to the bottom heater 4c below the bottom surface 3b of the crucible 3. In addition, when the fluid level of the silicon melt L is reduced to a fluid level that is about half the fluid level LS at the time the pulling is started, the output of the bottom heater 4c is controlled to be about 0.5 times the outputs of the side heaters 4a and 4b.

In the melting step S5, the magnetic field applying means B illustrated in FIG. 1 applies a magnetic field to the crucible 3 to generate such a temperature gradient that the temperature of the peripheral portion is higher than that of the center portion of the crucible 3. The applied magnetic field may be a horizontal magnetic field or cusp magnetic field. With regard to the strength of the applied magnetic field, the strength of the horizontal magnetic field is set to be equal to or greater than 2000 G, and the strength of the cusp magnetic field is set to be equal to or greater than 400 G. In addition, the center height of the magnetic field is set to be within the range from the bottom surface 3b to the upper end 3d of the crucible 3. At this state, the melting step S5 is started.

In addition, in the melting step S5, with regard to a time T from the start of melting to the end of melting, the center height of the applied magnetic field from the start of melting to T/3, is set to be in the range of ⅛ to ⅓ of the height of the crucible 3 from the bottom surface 3b of the crucible 3, the center height of the magnetic field from the 2T/3 to the end of melting, is set to be in the range of the silicon melt surface LS at the time of end of melting to 10 cm from the silicon melt surface LS in a vertical direction, and the height of the magnetic field from T/3 to 2T/3, is controlled to correspond to the height of the crucible 3 which is changed as the raw material melts, so as to be moved slowly from the height at the start to the height at the end.

In addition, in the melting step S5, with regard to a time T from the start of melting to the end of melting, the strength of the applied magnetic field from 2T/3 to the end, is set to be constant at the highest strength, the magnetic field strength from the start to T/3, is set to be in the range of ⅛ to ⅓ of the highest strength, and the magnetic field strength from T/3 to 2T/3, is controlled to gradually change from the level at the start to the level at the end.

According to the embodiment, the RMS roughness of the inner surface of the crucible 3 may be set to be in the range of 3 to 50 nm. In addition, a devitrification layer of 10 to 1000 μm may be formed at the inner surface of the crucible 3.

In the melting step S5, the crucible 3 is rotated at 1 to 5 rpm and reversed at a period of 15 to 300 sec intervals by the rotation control means 2A. In addition, the rotation speed of the crucible 3 is periodically changed at a period of 0 to 5 rpm intervals by the rotation control means 2A.

In the pulling state controlling step S6, the lower end 7b of the heat cap 7 is set to be at a height SH2 of 10 to 50 cm from the silicon melt surface LS as illustrated in FIG. 8. Accordingly, with regard to the lower end 7b of the heat cap 7 which is spaced apart from the heater 4 such that the temperature of the lower end 7b of the heat cap 7 does not increase in the melting step S5 performed at a high temperature, between the melting step S5 and the time of pulling start, the flow of the melt L from the center portion of the crucible 3 toward the inner wall 3a can be prevented.

In addition, in the pulling state controlling step S6, the melt L may be left for 2 or more hours while the surface temperature thereof is maintained to be higher than the melting point of the silicon raw material by 15° C. or more. Specifically, it is preferable that the surface temperature of the melt L be higher than the melting point of the silicon raw material by 20° C. or higher, and a time to leave the melt be equal to or less than 10 hours.

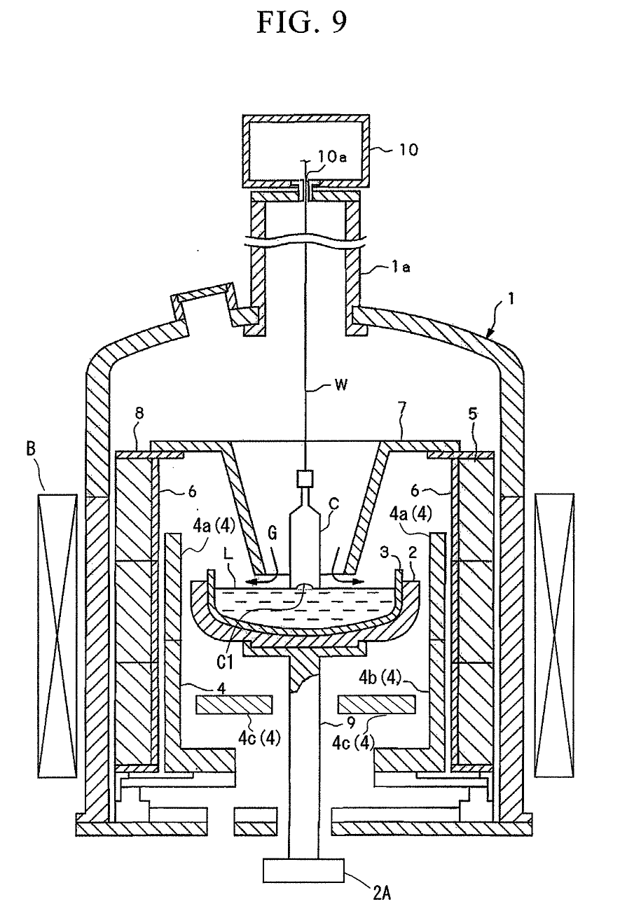

FIG. 9 is front view illustrating the pulling step in the carbon-doped single crystal manufacturing method according to the embodiment.

In the pulling step S7, as illustrated in FIG. 9, by a wire W made of W (tungsten) or the like hung inside a vertical cylindrical portion la at the upper portion of the chamber 1, a semiconductor single crystal C is pulled from the semiconductor melt L in the crucible 3 disposed below the vertical cylindrical portion la. In this case, in order to reduce the flow of the melt flowing from the inner wall 3a of the crucible 3 toward the center portion of the crucible 3 at the silicon melt surface LS, the lower end 7b of the heat cap 7 is set to be at the height SH2 of 1 to 20 cm from the silicon melt surface LS. Accordingly, the flow of gas G which is blown from the inner side of the heat cap to the vicinity of the silicon melt surface to flow outwards from the center portion of the crucible in the vicinity of the melt surface is formed as illustrated in FIG. 9.

In the pulling step S7, the internal pressure of the furnace in the chamber is set to be in the range of 1.3 to 6.6 kPa, and the gas flow rate of the gas flowing from the upper side of the heat cap toward the crucible is set to be in the range of 3 to 150 L/min.

In the pulling step S7, as illustrated in FIG. 9, in order to reduce the flow of the melt flowing from the inner wall 3a of the crucible 3 toward the center portion thereof at the silicon melt surface LS, the output of the heater 4 is controlled so that the solid-liquid interface C1 between the silicon melt L and the single crystal C is convex.

Specifically, with regard to the outputs of the upper side heater 4a, the lower side heater 4b, and the bottom heater 4c, the ratio of upper side heater 4a: lower side heater 4b is set to 3 to 1 and the output of the bottom heater 4c is set to 0.

In the pulling step S7, the pulling rate of a straight portion of the single crystal C is set to be in the range of 0.1 to 1.5 mm/min.

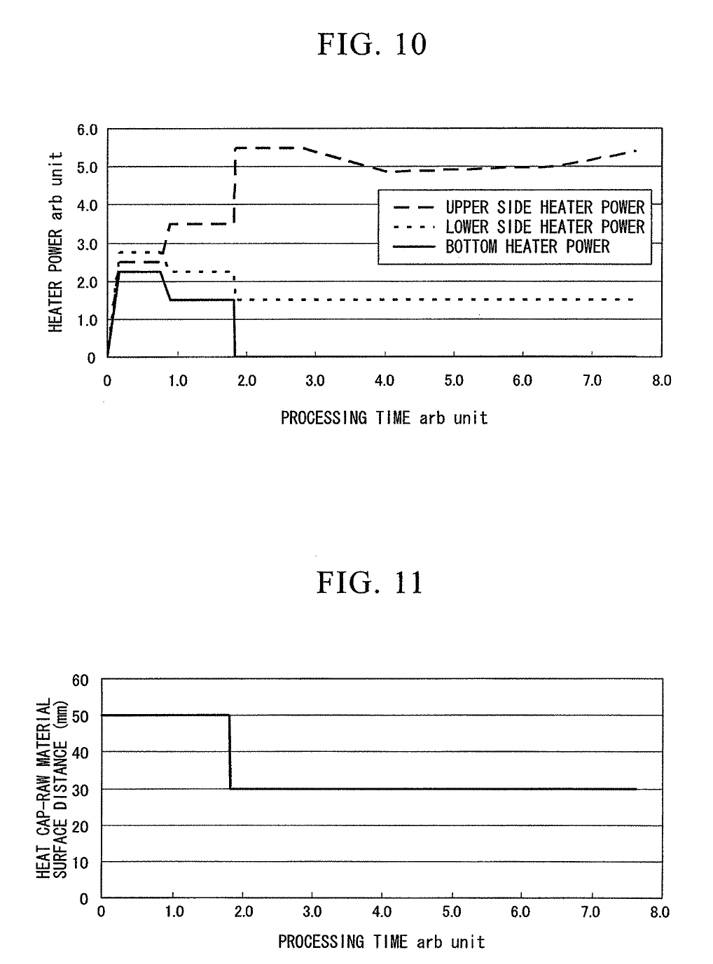

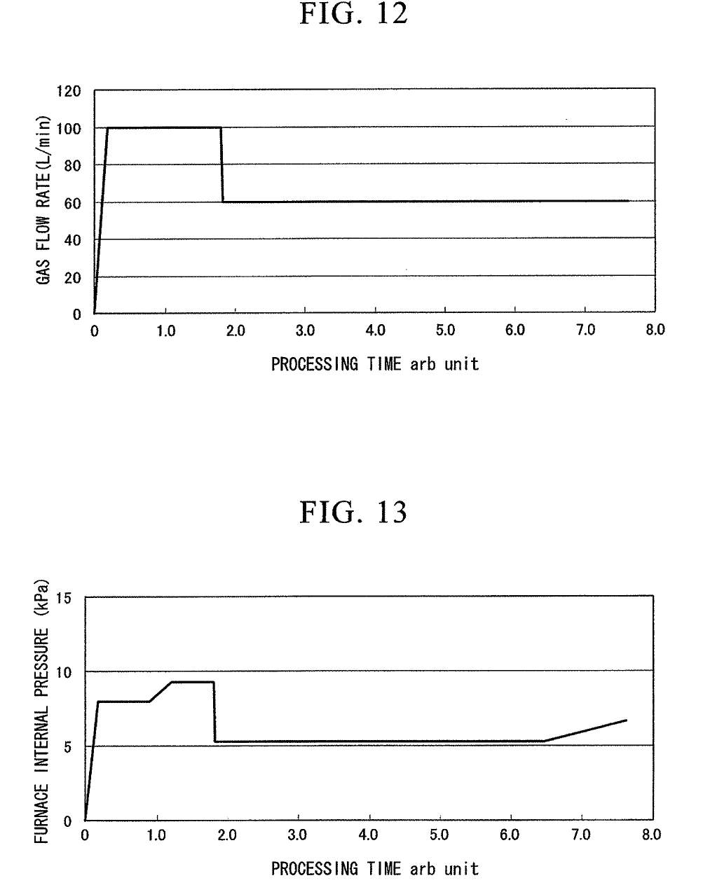

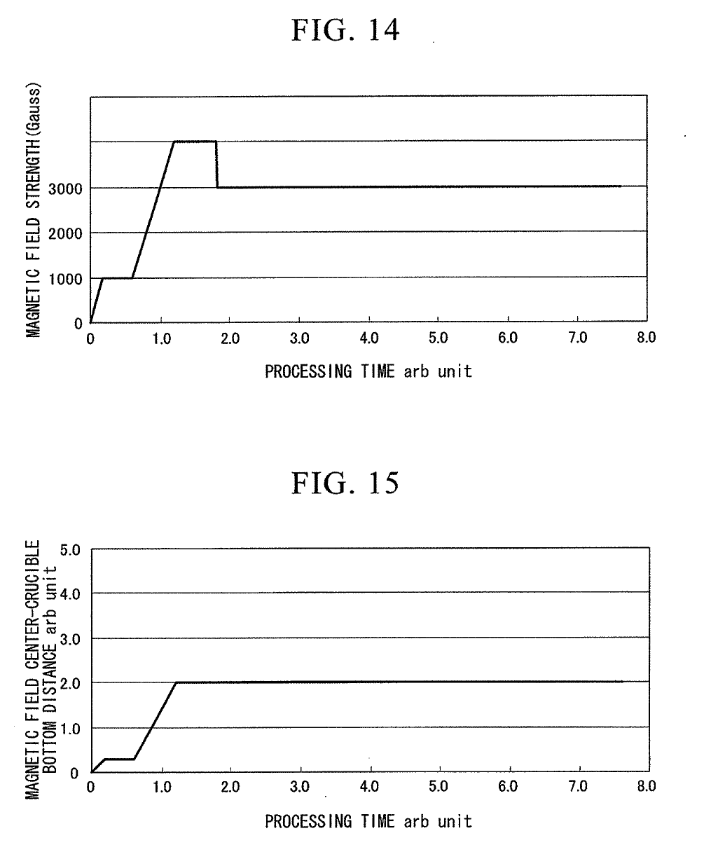

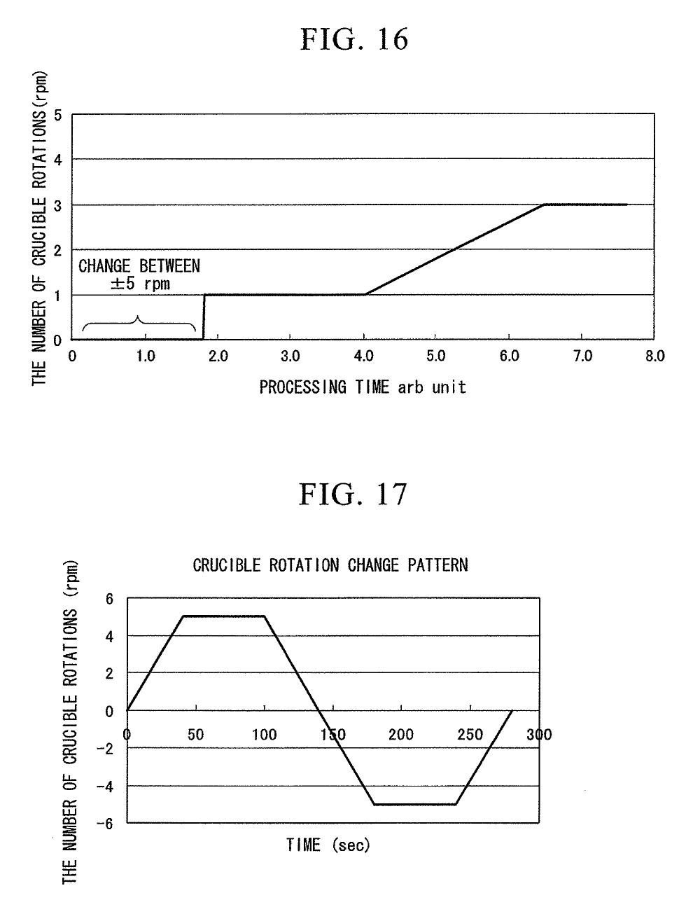

FIGS. 10 to 17 are time charts of parameters used in the carbon-doped single crystal manufacturing method according to the embodiment.

According to the embodiment, the heater outputs, the heat cap height, the gas flow rate, the furnace internal pressure, the magnetic field strength, the magnetic field height, and the crucible rotation are controlled as represented in FIGS. 10 to 17 and Tables 2 and 3 to allow the pulled silicon single crystal C to have an oxygen concentration of 0.1 to 18×10^{17 atoms/cm}³ (OLDASTM method) and a carbon concentration of 1 to 20×10¹⁶ atoms/cm³ (NEW ASTM method). In addition, control is made to allow the specific resistance of a wafer sliced from the pulled silicon single crystal to be in the range of 0.1 to 99 Ω·cm.

### EXAMPLES

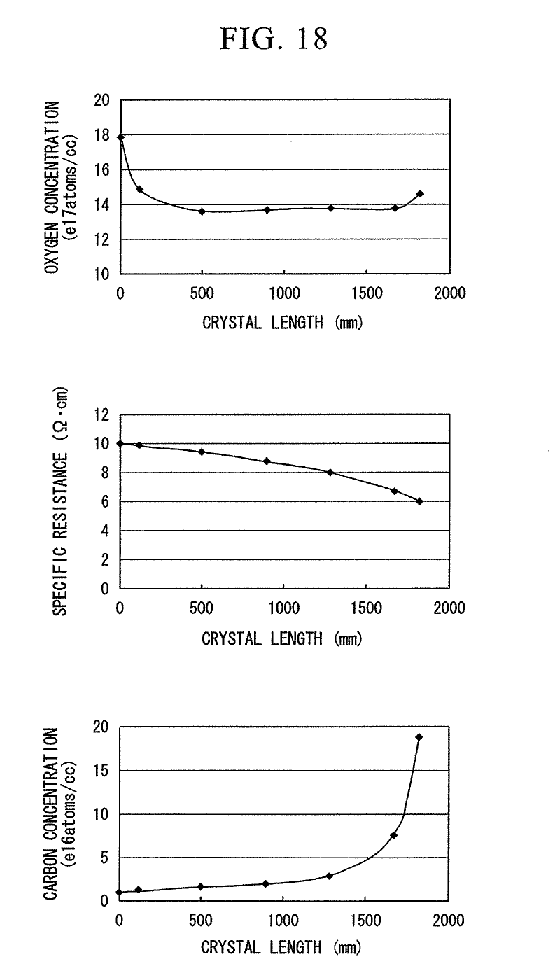

A carbon-doped crystal having a diameter of 306 mm was pulled from a melt of 400 kg by controlling the heater outputs, the heat cap height, the gas flow rate, the furnace internal pressure, the magnetic field strength, the magnetic field height, and the crucible rotation as represented in FIGS. 10 to 17 and Tables 2 and 3, related to target conditions of Table 3. The specific resistance, the oxygen concentration, and the carbon concentration in this case are shown in FIG. 18.

TABLE 1

| Specific | Oxygen | Carbon |
|---|---|---|
| Resistance | Concentration | Concentration |
| (Ω · cm) | (e17 atoms/cc) | (e16 atoms/cc) |
| 11 to 6 | 13 to 15 | 1 to 20 |

As seen from the results, a crystal with the aimed oxygen concentration, carbon concentration, and specific resistance could be pulled without causing dislocations over the entire region.

While preferred embodiments of the present invention have been described and illustrated above, it should be understood that these are exemplary of the present invention and are not to be considered as limiting. Additions, omissions, substitutions, and other modifications can be made without departing from the spirit or scope of the present invention. Accordingly, the present invention is not to be considered as being limited by the foregoing description, and is only limited by the scope of the appended claims.

1. A carbon-doped single crystal manufacturing method of manufacturing a silicon single crystal with carbon doping in a chamber using a Czochralski method, the method comprising the steps of:
placing a silicon raw material in a crucible;
disposing a carbon dopant at a distance of 5 cm or further away from the inner surface of the crucible; and
melting the silicon raw material after the disposing step.

2. The method according to claim 1, wherein, the step of placing the silicon raw material in the crucible comprises:
disposing the carbon dopant at a distance of 5 cm or inwards from the top surface of the placed silicon raw material, and
melting the silicon raw material after the disposing step.

3. The method according to claim 1, wherein the step of placing the silicon raw material in the crucible includes:
disposing the carbon dopant, in the placed silicon raw material, with respect to the height H from the bottom surface of the crucible to the top surface of the silicon raw material, at a position in the range of the center position, that is, H/2, to positions from the center position by H/4 in a vertical directions, and
melting the silicon raw material after the disposing step.

4. The method according to claim 1, wherein the step of placing the silicon raw material in the crucible includes:
disposing the carbon dopant, with respect to the radius R of the crucible, at a position in the range of the center of the crucible to R/2 in a transverse direction, from a plan view, and
melting the silicon raw material after the disposing step.

5. The method according to claim 1, wherein the carbon dopant is carbon powder.

6. The method according to claim 5, wherein the carbon dopant is carbon powder with a purity of 99.999%.

7. The method according to claim 5,
wherein the placed silicon raw material includes a lumpy raw material of 10 cm² or larger at least from a plan view,
the lumpy, silicon raw material has a shape of a plane so as to enable the carbon dopant to be put thereon, and
the carbon dopant is put on the lumpy, silicon raw material.

8. The method according to claim 1, wherein the carbon dopant is in a form of a sheet.

9. The method according to claim 8, wherein the placed silicon raw material includes a lumpy raw material having a slit in which at least the carbon dopant is to be disposed.

10. The method according to claim 9, wherein the slit of the silicon raw material has such a size that al least half the area of the sheet-shaped carbon dopant is inserted into the slit.

11. The method according to claim 1, wherein, when controlling a melting state after the disposing step,
the lower end of a heat cap which is disposed concentrically above the crucible and substantially cylindrical is at a height of 20 to 50 cm from the top surface of the placed silicon raw material, and at this state
melting of the silicon raw material is started.

12. The method according to claim 11, wherein, in the step of controlling the melting state,
the internal pressure of a furnace in the chamber is set to be in the range of 2 to 13.3 kPa,
the gas flow rate of a gas flowing from the upper side of the heat cap toward the crucible is set to be in the range of 3 to 150 L/min, and at this state,
melting of the silicon raw material is started.

13. The method according to claim 1, wherein in the melting step, a heater is controlled so that the upper side of the silicon raw material melts before the lower side thereof melts.

14. The method according to claim 1, wherein, in the melting step, a magnetic field is applied to the crucible to generate such a temperature gradient that the temperature of the peripheral portion of the crucible is higher than that of the center portion of the crucible.

15. The method according to claim 14,
wherein, in the melting step, with regard to the magnetic filed strength, the strength of the horizontal magnetic field is set to be in the range of 1000 to 5000 G, the strength of the cusp magnetic field is set to be in the range of 300 to 1000 G, and the center height of the magnetic field is set to be within the range from the bottom to the upper end of the crucible,
the melting step includes the steps of:
with regard to a time T from the start of melting to the end of melting, setting the center height of the magnetic field from the start of melting to T/3, to be in the range of ⅛ to ⅓ of the height of the crucible from the bottom of the crucible;
setting the center height of the magnetic field from the 2T/3 to the pulling end, to be in the range of the silicon melt surface at the time of end of melting to 10 cm from the silicon melt surface in a vertical direction; and
controlling the height of the applied magnetic field from T/3 to 2T/3, to correspond to the height of the crucible which is changed as the raw material melts, so as to be moved slowly from the height at the start to the height at the end, and
the melting step includes the steps of:
with regard to a time T from the start of melting to the end of melting,
setting the magnetic field strength from 2T/3 to the end, to be constant at the highest strength;
setting the magnetic field strength from the start to T/3, to be in the range of ⅛ to ⅓ of the highest strength; and
controlling the strength of the applied magnetic field from T/3 to 2T/3, to gradually change from the level at the start to the level at the end.

16. The method according to claim 1, wherein the RMS roughness of the inner surface of the crucible is within in the range of 3 to 50 nm.

17. The method according to claim 1, wherein a devitrification layer of 10 to 1000 μm is formed at the inner surface of the crucible.

18. The method according to claim 1, wherein, in the melting step, the crucible is rotated at 1 to 5 rpm and reversed at a period of 15 to 300 sec intervals.

19. The method according to claim 1, wherein 1×10⁻⁶ to 10 g of the carbon dopant is disposed in the crucible.

20. The method according to claim 1, wherein an oxygen concentration and a carbon concentration are controlled to be 0.1 to 18×10¹⁷ atoms/cm³ (OLDASTM method) and 20×10¹⁶ atoms/cm³ (New ASTM method), respectively, in the pulled silicon single crystal.

21. The method according to claim 1, wherein control is made to allow the specific resistance of a wafer sliced from the pulled silicon single crystal to be in the range of 0.1 to 99 Ω·cm.

22. The method according to claim 1, wherein, in a step of pulling a single crystal after the melting step, the lower end of a heat cap which is disposed concentrically above the crucible and substantially cylindrical is at a height of 1 to 20 cm from the silicon melt surface in order to reduce the flow of the melt flowing from the inner surface toward the center portion of the crucible at the silicon melt surface.

23. The method according to claim 22, wherein, in a step of controlling a pulling state between the melting step and the pulling step, the lower end of the heat cap which is disposed concentrically above the crucible and substantially cylindrical is at a height of 10 to 50 cm from the silicon melt surface.

24. The method according to claim 1, wherein, in a step of pulling a single crystal after the melting step, from a plan view at the lower end of a heat cap which is disposed concentrically above the crucible and substantially cylindrical to reduce the flow of the melt flowing from the inner surface toward the center portion of the crucible at the silicon melt surface, the internal pressure of a furnace in the chamber is set to be in the range of 1.3 to 6.6 kPa, and the gas flow rate of a gas flowing from the upper side of the heat cap toward the crucible is set to be in the range of 3 to 150 L/min, in order to prevent the incorporation of factors such as SiC and impurities which cause dislocations.

25. The method according to claim 1, wherein, in a step of pulling a single crystal after the melting step, from a plan view at the lower end of a heat cap which is disposed concentrically above the crucible and substantially cylindrical to reduce the flow of the melt flowing from the inner surface toward the center portion of the crucible at the silicon melt surface, the heater output is controlled so that the solid-liquid interface between the silicon melt and the single crystal is convex, in order to prevent the incorporation of SiC.

26. The method according to claim 1, wherein, in a step of pulling a single crystal after the melting step, the pulling rate of a straight portion of a single crystal is in the range of 0.1 to 1.5 mm/min.

27. A carbon-doped single crystal manufacturing apparatus for pulling a single crystal by the method according to claim 1, comprising:
a chamber;
a crucible in the chamber;
a side heater provided in the vicinity of the crucible; and
dopant position setting means for setting the position of a carbon dopant to be disposed at a distance of 5 cm or further away from the inner surface of the crucible when a silicon raw material is placed in the crucible.

28. The apparatus according to claim 27, wherein the dopant position setting means includes:
detection means for detecting the upper end position of the crucible, and the height and horizontal position of the carbon dopant as the relative position to the crucible; and
display means for displaying the output from the detection means.

29. The apparatus according to claim 28, wherein the dopant position setting means includes:
memory means for registering position data on the carbon dopant in advance;
computing means for comparing the output of the detection means to the data of the memory means; and
the display means for displaying the computational result.

30. The apparatus according to claim 27, wherein the dopant position setting means includes:
a crucible upper end position detection bar member hung at the side wall of the crucible to pass through the center position of the crucible; and
a height setting bar member provided vertically downward from the center position of the crucible upper end position detection bar member.

31. The apparatus according to claim 27,
wherein the internal pressure of a furnace in the chamber is set to be in the range of 1.3 to 6.6 kPa,
the gas flow rate of a gas flowing from the upper side of the heat cap toward the crucible is set to be in the range of 3 to 150 L/min, and in this state
melting of the silicon raw material is started.

32. The apparatus according to claim 27, further comprising a bottom heater provided below the crucible,
wherein the output of the side heater is set to be greater than that of the bottom heater in the step of melting the silicon raw material.

33. The apparatus according to claim 27, further comprising magnetic field applying means provided outside the crucible,
wherein a magnetic field is applied to the crucible in the step of melting the silicon raw material and a step of pulling a single crystal.

34. The apparatus according to claim 27, wherein the RMS roughness of the inner surface of the crucible is set to be in the range of 3 to 50 nm.

35. The apparatus according to claim 27, wherein a devitrification layer of 10 to 1000 μm is formed at the inner surface of the crucible.

36. The apparatus according to claim 27, further comprising crucible rotation control means for rotating the crucible at 1 to 5 rpm and reversing the crucible at a period of 15 to 300 sec intervals in the melting step.
